(19) United States
(12) Patent Application Publication
(10) Pub. No.: US 2005/0020001 A1
(43) Pub. Date: Jan. 27, 2005

(54) Selective treatment of the surface of a microelectronic workpiece

(76) Inventors: Brian Aegerter, Kalispell, MT (US); Curt T. Dundas, Kalispell, MT (US); Michael Jolley, Kalispell, MT (US); Tom L. Ritzdorf, Kalispell, MT (US); Steven L. Peace, Kalispell, MT (US); Gary L. Curtis, Kalispell, MT (US); Raymon F. Thompson, Kalispell, MT (US)

Correspondence Address: WALLENSTEIN WAGNER & ROCKEY, LTD., 311 SOUTH WACKER DRIVE, 53RD FLOOR, CHICAGO, IL, 60606, US

(21) Appl. No.: 10/927,259

(22) Filed: Aug. 25, 2004

Related U.S. Application Data
(63) Continuation of application No. 10/285,017, filed on Oct. 30, 2002, now abandoned.
Application No. 10/285,017 is a continuation of application No. 10/150,631, filed on May 17, 2002.
(63) Continuation of application No. 10/184,141, filed on Jun. 26, 2002.
Application No. 10/184,141 is a division of application No. 09/437,926, filed on Nov. 10, 1999, now Pat. No. 6,413,436.
Application No. 10/184,141 is a continuation of application No. 09/881,246, filed on Jun. 12, 2001, now Pat. No. 6,446,643.
Application No. 09/881,246 is a division of application No. 09/041,649, filed on Mar. 13, 1998, now Pat. No. 6,318,385.
(60) Provisional application No. 60/117,474, filed on Jan. 27, 1999.

(30) Foreign Application Priority Data
Mar. 15, 1999 (WO) PCT/US99/05674

(51) Int. Cl. H01L 21/8238

(52) U.S. Cl. 438/199

(57) ABSTRACT

In a process for treating a workpiece such as a semiconductor wafer, a processing fluid is selectively applied or excluded from an outer peripheral-margin of at least one of the front or back sides of the workpiece. Exclusion and/or application of the processing fluid occurs by applying one or more processing fluids to the workpiece while the workpiece and a reactor holding the workpiece are spinning. The flow rate of the processing fluids, fluid pressure, and/or spin rate are used to control the extent to which the processing fluid is selectively applied or excluded from the outer peripheral margin.

This Application is a Division of U.S. patent application Ser. No. 09/437,926 filed Nov. 10, 1999 and now pending, which is the U.S. National Stage Application of International Application No. PCT/US99/05674, filed on Mar. 15, 1999 and published in English, and including priority claims to U. S. Provisional Patent Application Nos. 60/116,750, filed Jan. 23, 1999; 60/117,474, filed Jan. 27, 1999; and to U.S. patent application Ser. Nos. 09/041,901, filed Mar. 13, 1998, now U.S. Pat. No. 6,350,319; 09/041,649, filed Mar. 13, 1998, now U.S. Pat. No. 6,318,385; and 09/113,435, filed Jul. 10, 1998, now U.S. Pat. No. 6,264,752. This Application claims priority to each of these applications. The disclosures of PCT/US99/05674; 60/117,474; and U.S. patent application Ser. No. 09/437,711 are incorporated by reference.

### BACKGROUND OF THE INVENTION

This invention pertains to treating a silicon wafer to remove a thin film, such as a copper film, from regions on the silicon wafer.

The fabrication of a microelectronic circuit and/or component from a substrate typically involves a substantial number of processes. Many of these processes involve the deposition of a thin film on the surface of the workpiece followed by contact with a processing liquid, vapor, or gas. In a known process for treating a microelectronic workpiece, such as a silicon wafer, on which microelectronic devices have been fabricated, thin-film layers are successively applied and etched to form, for example, a metallized interconnect structure. In a typical metallization process, a barrier layer is applied over a dielectric layer on the front side of the workpiece. Depending upon the particular process used to form the interconnect structures, the dielectric layer may include a pattern of recessed micro-structures forming the various interconnect paths. A thin metal film, such as a copper film, is applied exterior to the barrier layer. In most instances, the thin film serves as an initial seed layer for subsequent electroplating of a further metal layer, such as a further copper layer. Due to manufacturing constraints, the thin film is not applied over an outer, peripheral margin of the front side.

Known techniques, such as physical vapor deposition (sputtering) or chemical vapor deposition, are typically used to apply the barrier layer and the thin film. If a further metal layer is to be electroplated exterior to the thin film, one or more electrical contacts are connected to an outer margin of the thin film to provide plating power.

The surface area of the front side beyond the inner boundary of the outer margin of the thin film is not available for fabricating the microelectronic devices since the present manufacturing processes limit the extent to which device structures can be formed at the outer margin. It would be highly desirable and would result in increased yield if more surface area beyond the present limits of the outer margin of the thin film were available for fabricating interconnect structures.

In the known process discussed above, and in other processes, contamination by copper, other metals, or other contaminants can occur on the back side of the workpiece. Although copper and other metals tend to diffuse rapidly through silicon or silicon dioxide, the back side is generally not provided with barrier layers capable of preventing copper, other metals, or other contaminants from diffusing through the silicon wafer to the front side, where such contamination can be very detrimental to device performance.

Such contamination can result from overspraying or other processing artifacts or from cross-contamination via fabrication tools. Such contamination can occur on the outer perimeter of a silicon wafer as well as on its back side. If not removed, such contamination can lead to cross-contamination of other wafers, via fabrication tools. Such contamination can be very difficult to remove, particularly if the contaminant has formed a stable silicide. It would be highly desirable if such contamination could be easily removed in a controlled manner without detrimentally affecting the front side of the workpiece.

### SUMMARY OF THE INVENTION

In a first aspect of the invention, a processing fluid is selectively applied or excluded from an outer peripheral margin of at least one of the front or back sides of the workpiece. Exclusion and/or application of the processing fluid occurs by applying one or more processing fluids to the workpiece as the workpiece, and a reactor holding the workpiece, are spinning. The flow rate of the one or more processing fluids, fluid pressure, and/or spin rate are used to control the extent to which the processing fluid is selectively applied or excluded from the outer peripheral margin.

In a second aspect of the invention, a thin film is applied over the front side and over at least a portion of the outer perimeter. A barrier layer may be applied over the front side and over at least a portion of the outer perimeter, whereupon a further thin film, such as a conductive seed layer, is applied over the barrier layer.

After one or more further intervening steps, such as electroplating of a metal layer onto the conductive seed layer, an etchant capable of removing one or more of the thin film layers is caused to flow over an outer margin of the front side while the etchant is prevented from flowing over the front side except for the outer margin. Thus, the etchant only contacts the outer margin of the front side thereby selectively removing only the one or more thin film layers from the outer margin of the front side. If the etchant is also caused to flow over the back side and over the outer perimeter, as well as over the outer margin of the front side, the one or more thin film layers are removed from the outer perimeter and any contaminant that the etchant is capable of removing is stripped from the back side as well. A cleaning chemical can be used instead of an etchant in some applications to remove or dissolve the one or more thin film layers as described above.

These and other objects, features, and advantages of this invention are evident from the following description of a preferred mode for carrying out this invention, with reference to the accompanying drawings.

### BRIEF DESCRIPTION OF THE DRAWINGS

FIGS. 1A, 1B, 1C, and 1D are fragmentary, cross-sectional views of a microelectronic workpiece, such as a silicon wafer, at various stages of a known sequence of processing steps in accordance with prior art.

FIGS. 2A, 2B, 2C, and 2D are fragmentary, cross-sectional views of a microelectronic workpiece, such as a silicon wafer, at various stages of a novel sequence of processing steps in accordance with this invention.

FIGS. 3 and 4 illustrate one embodiment of a reactor that can be used to implement the process of the present invention.

### DETAILED DESCRIPTION OF ONE EMBODIMENT OF THE INVENTION

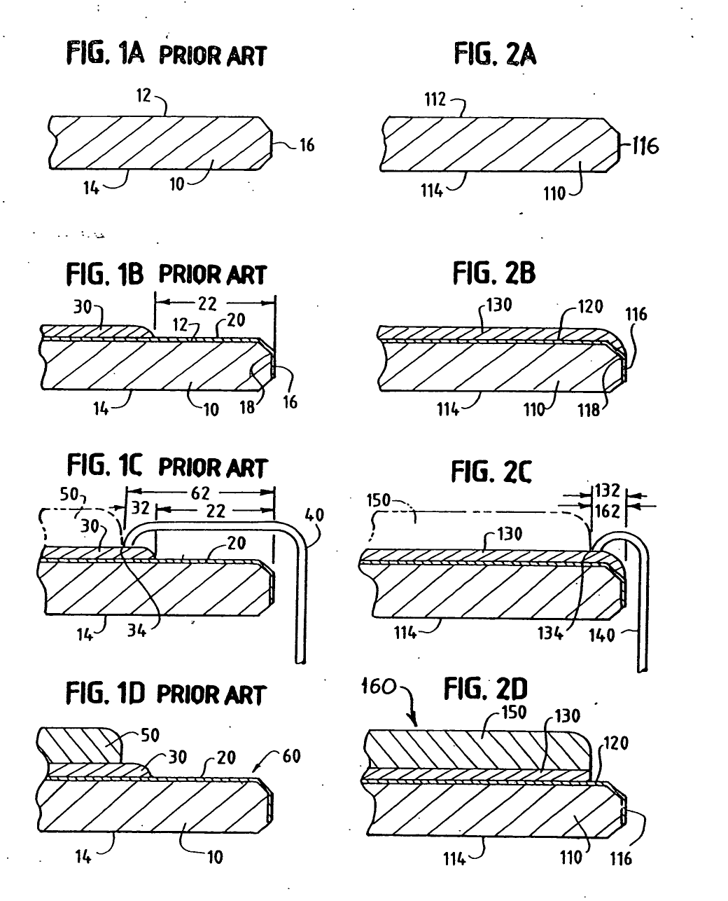

Although the process of the present invention has applicability to any process in which a processing fluid is selectively provided to or excluded from an outer margin of a workpiece, the invention will be described in connection with a sequence of processing steps for depositing one or more metallization layers or metallized structures on the workpiece. The known sequence of processing steps in accordance with the prior art begins with a silicon wafer 10, on which microelectronic devices (not shown) have been fabricated. As illustrated in FIG. 1A, the wafer 10 has a front, device side 12, a back, non-device side 14, and a beveled, outer perimeter 16. Via physical vapor deposition (sputtering) or chemical vapor deposition, a barrier layer 20 is applied over the front side 12 and over an upper portion 18 of the outer perimeter 16. A thin-film seed layer, such as a copper film 30, is applied over the barrier layer 20. Conventionally, the seed layer 30 is only deposited within the bounds of an outer margin 22 of the barrier layer 20, as illustrated in FIG. 1B. At an outer edge 32 of the seed layer, or copper film 30, one or more electrical contacts 40 to be used in providing electroplating power to the seed layer are placed in electrical contact with the copper film 30, as illustrated in FIG. 1C.

After the one or more electrical contacts 40 have been connected to the seed layer copper film 30 a further copper layer 50 from which interconnect structures and/or metallized devices are fabricated is electroplated onto the wafer 10 as illustrated in FIG. 1C. The electrical contact(s) 40 are then removed to provide the resultant multi-film structure, shown generally at 60 in FIG. 1D. Beyond an inner boundary 34 of the outer margin 32 of the copper layer 50, an annular region 62 of the front side 12 is not available for fabricating such interconnect structures or metallized devices.

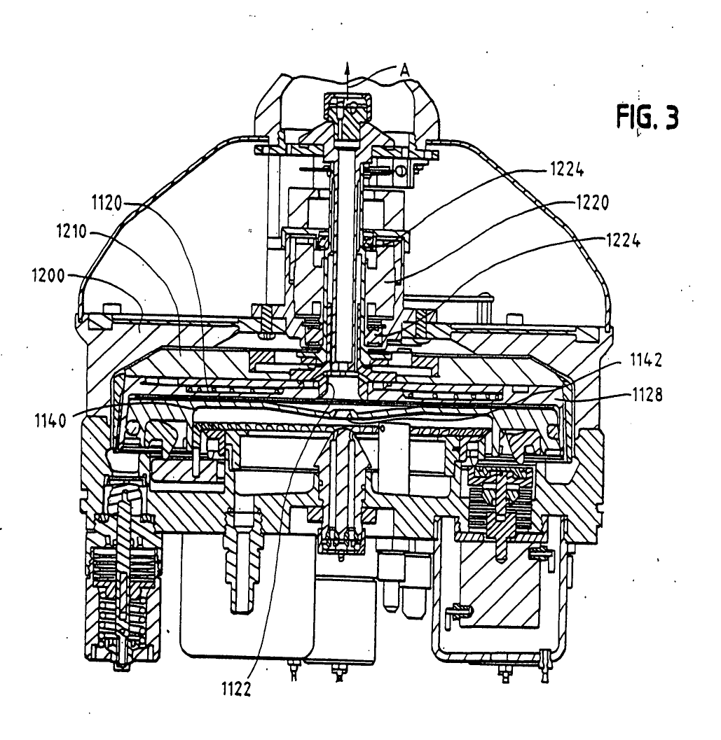

The processing steps of the invention, as shown in FIGS. 2A-2D, begin with a silicon wafer 110, which is similar to the silicon wafer 10 before processing, on which microelectronic devices (not shown) have been fabricated, and which has a front, device side 112, a back, non-device side 114, and a beveled, outer perimeter 116. Via physical vapor deposition (sputtering) or chemical vapor deposition, a barrier layer 120 is applied over the front side 112 and over an upper portion 118 of the outer perimeter 116 and a thin seed layer, such as a copper film 130 is applied over the entire barrier layer 120, without exclusion from a peripheral outer margin, so as to cover the barrier layer 120 where applied over the front side 112 and over the upper portion 118 of the outer perimeter 116, as illustrated in FIG. 2B. At an outer edge 132 of the copper seed layer 130, one or more electrical contacts 140 to be used in electroplating are connected to provide electroplating power to the copper film 130, as illustrated in FIG. 2C. As illustrated, the outer edge 132 at which contact may be made for the supply of electroplating power illustrated in FIG. 2C is substantially closer to the peripheral edge than the process as illustrated in FIG. 1C.

A further copper film 150 from which metallized interconnects and/or microelectronic devices are fabricated is then applied using an electrochemical deposition process. As illustrated in FIG. 2C, the further copper film 150 is deposited inside of the outer margin 132 of the copper film 130, up to the boundary designated by 134. The electrical contact 140 is then removed leaving the resultant multi-layer structure shown generally at 160 of FIG. 2D. Metallized devices (not shown) and/or interconnects are formed by known techniques, from the resultant structure 160. After the copper layer 150 has been deposited, the seed layer 130, film 150, and/or barrier layer 120 may be removed from the outer margin 132 and, if desired peripheral edge 116 of the workpiece 110. Removal of at least layer 130 from the outer margin assists in preventing film flaking and cross-contamination problems that may occur during subsequent workpiece processing.

In accordance with the process, a liquid processing fluid is selectively applied to the outer peripheral margin of at least the front side of the workpiece. Exclusion and/or application of the processing fluid occurs by applying one or more processing fluids to the workpiece as the workpiece and corresponding reactor are spinning about an axis of rotation that is generally parallel (or antiparallel) to the vector defining the face of the workpiece being processed. The flow rate of the one or more processing fluids, fluid pressure, and/or spin rate are used to control the extent to which the processing fluid is selectively applied to the outer peripheral margin.

A reactor suitable for executing the foregoing removal process may generally be comprised of upper and lower members that define an upper chamber and a lower chamber with respect to the workpiece contained therein. A centrally disposed inlet is provided to each of the upper an lower chambers for supplying one or more processing fluids. Fluid outlets are disposed at peripheral portions of the chambers and are adapted to assist in the exclusion of one processing fluid from the outer margin of the workpiece while allowing intrusion of an etchant thereat. The upper and lower chambers are rotated together to distribute a processing fluid in the upper chamber across an upper side of the workpiece through centripetal acceleration and to distribute a processing fluid in the lower chamber across a lower side of the workpiece through centripetal acceleration. Depending upon the processes being performed, however, the processing fluids in the upper and lower chambers may be the same fluid or different fluids.

Also rather than relying on the rotation of the workpiece, the processing fluid could also be selectively driven by pumps.

Through control of the respective pressures of the processing fluids entering the respective chambers and of the rotational speed of the rotating chambers, it is possible to control the reactor to cause the processing fluid entering the inlet of the lower chamber to flow over the near side of the wafer, over the outer perimeter of the workpiece, and over an outer margin of the far side of the workpiece, and to prevent the same processing fluid from flowing over the far side except for the outer margin. The control of the fluid pressures may be achieved for example through the use of a pump for liquids, or a pressure regulator for a pressurized gas source.

The process provided by this invention can be advantageously practiced in a reactor illustrated and described in PCT/US99/05674, PCT/US99/05676, and U.S. Pat. No. 6,264,752, incorporated herein by reference.

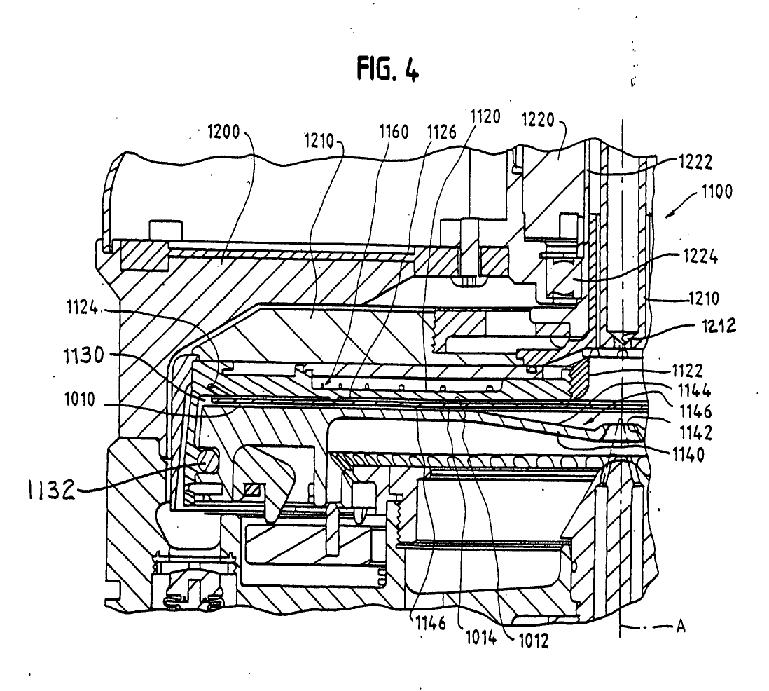

As shown in the FIGS. 3 and 4, a reactor 1100 for processing a microelectronic workpiece, such as a silicon wafer 1010 having an upper side 1012, a lower side 1014, and an outer, circular perimeter 1016, in a micro-environment constitutes a preferred platform for the practice of the process of this invention. For certain applications, the upper side 1012 is the front side, which may be otherwise called the device side, and the lower side 1014 is the back side, which may be otherwise called the non-device side. However, for other applications, the silicon wafer 1010 is inverted.

Generally, except as disclosed herein, the reactor 1100 is similar to the reactors illustrated and described in U.S. Pat. No. 6,264,752. However, as illustrated in the drawings and described herein, the reactor 1100 is improved to be more versatile in executing select microelectronic fabrication processes.

The reactor 1100 has an upper chamber member or rotor that includes an upper chamber wall 1120 and a lower chamber member or rotor that includes a lower chamber wall 1140. These walls 1120, 1140, are arranged to open so as to permit a wafer 1010 to be loaded into the reactor 1100 for processing, by a loading and unloading mechanism (not shown) that, for example, may be in the form of a robot having an end effector. These walls 1120, 1140, are arranged to close so as to define a capsule 1160 supporting a wafer 1010 in a processing position, between these walls 1120, 1140.

The reactor 1010 has an head 1200 containing a rotor assembly 1210 supported by bearings 1124. A motor 1220 for rotating the rotor 1210, about a vertical axis A is supported in the head 1200.

The rotor assembly includes the upper rotor and a lower rotor which can be moved vertically apart, for loading and unlading, and which can be brought together, for processing a wafer. The upper rotor has an inlet 1122 in an upper chamber wall 1120 for entry of processing fluids, which may be liquid, vaporous, or gaseous. The lower rotor similarly has a lower chamber wall 1140 with an inlet 1142 for such fluids. A nozzle 1212 in the head 1200 extends axially through a sleeve 1222, so as not to interfere with the rotation of the sleeve 1222. The upper nozzle 1212 directs streams of processing fluids downwardly through the inlet 1122 of the upper chamber wall 1120.

The upper chamber wall 1120 includes an array of similar outlets 1124, which are spaced similarly at uniform angular spacings around the vertical axis A. In the disclosed embodiment, thirty-six such outlets 1124 are employed. The outlets 1124 are spaced radially apart on a circle, with each outlet at the same distance from axis A. The outlets are located near the outside circumference of the rotors, typically about 1.5 mm in from the edge of the rotors.

When the upper and lower chamber walls 1120, 1140, are closed, they define a micro-environment reactor 1160 having an upper processing chamber 1126 that is defined by the upper chamber wall 1120 and by a first generally planar surface of the supported wafer 1010, and a lower processing chamber 1146 that is defined by the lower chamber wall 1140 and a second generally planar surface of the supported wafer opposite the first side. The upper and lower processing chambers 1126, 1146, are in fluid communication with each other in an annular region 1130 beyond the outer perimeter 16 of the supported wafer 1010 and are sealed by an annular, compressible seal (e.g. O-ring) 1132 bounding a lower portion 1134 of the annular region 1130. The seal 1132 allows processing fluids entering the lower inlet 1142 to remain under sufficient pressure to flow toward the outlets 1124.

The reactor 1100 is particularly suitable for executing a range of unique microfabrication processes. For example, reactor 1100 is particularly suited to execute a process that requires complete contact of a processing fluid at a first side of a workpiece and at only a peripheral margin portion of the second side thereof. Such processes may be realized because processing fluids entering the inlet 1142 of the lower chamber wall 1140 can act on the lower side 1014 of a supported wafer 1010, on the outer periphery 1016 of the supported wafer 1010, and on an outer margin 1018 of the upper side 1012 of the supported wafer 10 before reaching the outlets 1124, and because processing fluids entering the inlet 1122 of the upper chamber wall 1120 can act on the upper side 1012 of the supported wafer 1010, except for the outer margin 1018 of the upper side 1012, before reaching the outlets 1124.

When the reactor illustrated and described above is employed to practice the process provided by this invention for treating a silicon wafer having a front, device side, a back, non-device side, and an outer perimeter, so as to remove a thin film, such as a copper film, the silicon wafer is placed into the reactor with its back side being the lower side. An etchant capable of removing the copper is used as the processing. The etchant is delivered by a pump to the lower chamber and inert gas is used as the processing fluid entering the upper chamber. The etchant is caused to flow over the back side, over an outer perimeter of the silicon wafer, and over an outer margin of the front side, but is prevented from flowing over the front side except for the outer margin. After the etchant removes the thin film, any residual etchant is rinsed away, as with deionized water.

The processing fluid can be a mixture of an acid and an oxidizing agent.

If the thin film is a metal film, such as a copper film, a preferred etchant is a mixture of hydrofluoric acid and hydrogen peroxide, as an oxidizing agent, most preferably 0.5% hydrofluoric acid and 10% hydrogen peroxide, by volume, with the remainder being deionized water. An alternative reagent is approximately 10% sulfuric acid, although other concentrations of sulfuric acid from approximately 5% to approximately 98%, along with approximately 0% to 20% of an oxidizing agent, can be instead used to remove a metal film, such as a copper film.

The processing fluid can also be a mixture of sulfuric acid and amonium persulfate.

Other alternative reagents that can be instead used to remove a metal film, such as a copper film, include mixtures of hydrofluoric acid and a surfactant, mixtures of hydrofluoric and hydrochloric acids, mixtures of nitric and hydrofluoric acids, and EKC 5000, which is a proprietary reagent available commercially from EKC of Hayward, Calif.

When the resultant structure 160 illustrated in FIG. 2D is compared to the resultant structure 60 illustrated in FIG. 1D, it is evident that the annular region 162 not available for fabricating such interconnect structures and/or metallized components from the resultant structure 160 is smaller than the annular region 62 that is not available for fabricating such interconnect structures and/or metallized components on the resultant structure 60, all other dimensions being alike. It follows that this invention enables a greater yield of microelectronic devices from a silicon wafer of a given size. Advantageously, the process provided by this invention not only removes a thin film, such as a copper film, but also removes any contaminant, such as any copper or other metal, that the reagent is capable of solvating from the back side of the silicon wafer.

The thin film removed by the process of the present invention could also be substantially comprised of silicon nitride, silicone oxide, polysilicon, or photoresist.

Various modifications can, of course, be made without departing from the scope and spirit of the invention. The invention, therefore, should not be restricted, except by the following claims and their equivalents.

1-19. (canceled).

20. A method of removing unwanted metal deposited on an edge bevel area of a semiconductor wafer, the method comprising:
rotating the wafer; and
delivering a stream of liquid etchant onto the edge of the rotating wafer such that the liquid etchant selectively flows over the edge bevel area while in the viscous flow regime,
wherein the liquid etchant substantially removes unwanted metal selectively from the edge bevel area.

21. The method of claim 20, wherein the stream of liquid etchant is delivered onto the edge of the rotating wafer without substantially contacting any region of the wafer inside of the edge bevel area.

22. The method of claim 20, wherein the metal is copper provided by physical vapor deposition.

23. The method of claim 20, wherein the liquid etchant is delivered from a nozzle positioned proximate to the edge of the rotating wafer.

24. The method of claim 23, wherein the nozzle is pointed so that delivery of the liquid etchant has an angular component in the direction of rotation of the wafer edge and wherein the delivery direction has a radial component away from the center of the wafer and toward the edge of the wafer.

25. The method of claim 20, further comprising positioning the semiconductor wafer on a chuck prior to rotation.

26. The method of claim 20, further comprising prewetting a surface of the wafer prior to delivering the stream of liquid etchant.

27. The method of claim 20, further comprising rinsing the liquid etchant from the semiconductor wafer after removing the unwanted metal.

28. The method of claim 20, further comprising directing the liquid etchant at a backside of the semiconductor wafer to thereby etch unwanted metal that has deposited on the backside of the semiconductor wafer.

29. The method of claim 20, further comprising:
pre-wetting the semiconductor wafer prior to delivering the stream of the liquid etchant onto the edge of the rotating wafer;
rinsing the liquid etchant from the semiconductor wafer after the unwanted metal has been removed from the edge bevel area;
directing the liquid etchant onto the backside of the semiconductor wafer to remove unwanted metal that has been deposited on the backside of the semiconductor wafer; and
drying the semiconductor wafer,
wherein rotating the wafer, prewetting the wafer, delivering the stream of the liquid etchant, rinsing the liquid etchant, performing a backside etch, and drying the wafer are all performed within a single processing module.

30. A post-electrofill module including components for removing unwanted metal deposited on an edge bevel area of a semiconductor wafer, the module comprising:
a rotatable chuck; and
a liquid etchant delivery system including a nozzle which delivers a stream of liquid etchant onto the edge of the wafer while it rotates in the chuck, such that the liquid etchant selectively flows over the edge bevel area while in the viscous flow regime,
wherein the liquid etchant substantially removes unwanted metal selectively from the edge bevel area.

31. The module of claim 30, wherein the nozzle is positioned proximate the edge of the rotating wafer.

32. The module of claim 30, wherein the nozzle is pointed in a direction such that delivery of the liquid etchant has an angular component in the direction of rotation at the wafer edge and has a radial component away from the center of the wafer and towards the edge of the wafer.

33. The module of claim 30, further comprising one or more water delivery nozzles which deliver water to at least one of the front side of the semiconductor wafer and the backside of the semiconductor wafer.

34. The module of claim 30 wherein the metal is copper.

35. The module of claim 30 wherein the front edge area of the edge bevel area is confined to about 1.5 mm of the outer boundary of the semiconductor wafer.

36. The module of claim 30, wherein the liquid etchant comprises an aqueous solution comprising H₂SO₄ and H₂O₂.

37. The module of claim 30 wherein the liquid etchant is dispensed at an acute angle from the normal of the semiconductor wafer.

38. The module of claim 30, wherein the post electrofill module is provided in a system having a robot which delivers said semiconductor wafer to an electroplating module where the metal is deposited on the semiconductor wafer, and wherein the robot subsequently moves the semiconductor wafer to the post electrofill module.

39. The module of claim 38, wherein the electroplating module deposits copper and wherein the liquid etchant removes the electroplated copper from the edge bevel area.

40. An integrated module including components for electrofilling metal onto a semiconductor wafer and removing unwanted metal deposited on an edge bevel area from the semiconductor wafer, the module comprising:
a component for electrofilling metal onto the semiconductor wafer
a rotatable chuck; and
a liquid etchant delivery system including a nozzle which delivers a stream of liquid etchant onto the edge of the wafer while it rotates in the chuck, such that the liquid etchant selectively flows over the edge bevel area while in the viscous flow regime,
wherein the liquid etchant substantially removes unwanted metal selectively from the edge bevel area.

41. The module of claim 40, wherein the nozzle is positioned proximate to the edge of the rotating wafer.

42. The module of claim 40, wherein the nozzle is pointed in a direction such that delivery of the liquid etchant has an angular component in the direction of rotation at the wafer edge and has a radial component away from the center of the wafer and towards the edge of the wafer.

43. The module of claim 40, further comprising one or more water delivery nozzles which deliver water to at least one of the front side of the semiconductor wafer and the backside of the semiconductor wafer.

44. The module of claim 40 wherein the metal is copper.

45. The module of claim 40 wherein the front edge area of the edge bevel area is confined to about 1.5 mmn of the outer boundary of the semiconductor wafer.

46. The module of claim 40, wherein the liquid etchant comprises an aqueous solution comprising H₂SO₄ and H₂O₂.

47. The module of claim 40 wherein the liquid etchant is dispensed at an acute angle from the normal of the semiconductor wafer.

48. The module of claim 40, wherein the post electrofill module is provided in a system having a robot which delivers said semiconductor wafer to an electroplating module where the metal is deposited on the semiconductor wafer, and wherein the robot subsequently moves the semiconductor wafer to the post electrofill module.

49. The module of claim 48, wherein the electroplating module deposits copper and wherein the liquid etchant removes unwanted copper from the edge bevel area.

50. A method for removing metal from the front edge area of a semiconductor wafer, the method comprising:
applying an etchant to the front edge area of the semiconductor wafer under viscous flow conditions, so that etchant does not reach the interior active circuit region of the semiconductor wafer.

51. The method of claim 50 wherein the metal is in a physical deposition layer of copper and the etchant is an aqueous solution comprising H₂SO₄ and H₂O₂.

52. The method of claim 50 wherein the front edge area is confined to about 1.5 mm of the outer boundary of the semiconductor wafer.

53. The method of claim 50 wherein the etchant is dispensed at an acute angle from the normal of the semiconductor wafer.

54. The method of claim 50 wherein the etchant further flows onto the side edge area of the semiconductor wafer and onto the back edge area of the semiconductor wafer.

55. The method of claim 50 further comprising applying a second etchant to the back side of the semiconductor wafer to remove additional metal.

56. A method of removing unwanted metal deposited on an edge bevel area of a semiconductor wafer, the method comprising:
rotating the wafer; and
delivering a stream of liquid etchant onto the edge of the rotating wafer such that the liquid etchant selectively flows over the edge bevel area while the viscosity of the liquid etchant causes the liquid etchant to follow the curved surface of the edge bevel area,
wherein the liquid etchant substantially removes unwanted metal selectively from the edge bevel area.

57. A post-electrofill module including components for removing unwanted metal deposited on an edge bevel area of a semiconductor wafer, the module comprising:
a rotatable chuck; and
a liquid etchant delivery system including a nozzle which delivers a stream of liquid etchant onto the edge of the wafer while it rotates in the chuck, such that the liquid etchant selectively flows over the edge bevel area while the viscosity of the liquid etchant causes the liquid etchant to follow the curved surface of the edge bevel area,
wherein the liquid etchant substantially removes unwanted metal selectively from the edge bevel area.

58. An integrated module including components for electrofilling metal onto a semiconductor wafer and removing unwanted metal deposited on an edge bevel area from the semiconductor wafer, the module comprising:
a component for electrofilling metal onto the semiconductor wafer
a rotatable chuck; and
a liquid etchant delivery system including a nozzle which delivers a stream of liquid etchant onto the edge of the wafer while it rotates in the chuck, such that the liquid etchant selectively flows over the edge bevel area while the viscosity of the liquid etchant causes the liquid etchant to follow the curved surface of the edge bevel area,
wherein the liquid etchant substantially removes unwanted metal selectively from the edge bevel area.

59. A method for removing metal from the front edge area of a semiconductor wafer, the method comprising:
applying an etchant to the front edge area of the semiconductor wafer while the viscosity of the liquid etchant causes the liquid etchant to follow the curved surface of the edge bevel area, so that etchant does not reach the interior active circuit region of the semiconductor wafer.
